(19) United States
(12) Patent Application Publication
(10) Pub. No.: US 2020/0006166 A1
(43) Pub. Date: Jan. 2, 2020

(54) MICROELECTRONIC ASSEMBLIES

(71) Applicant: Intel Corporation, Santa Clara, CA (US)

(72) Inventors: Digvijay Raorane, Chandler, AZ (US); Mathew Manusharow, Phoenix, AZ (US)

(73) Assignee: Intel Corporation, Santa Clara, CA (US)

(21) Appl. No.: 16/022,152

(22) Filed: Jun. 28, 2018

(51) Int. Cl. H01L 23/13; H01L 23/64; H01L 23/15; H01L 23/498

(52) U.S. Cl. CPC H01L 23/13; H01L 23/645; H01L 23/49838; H01L 23/49827; H01L 23/15

(57) ABSTRACT

Disclosed herein are microelectronic assemblies, as well as related apparatuses and methods. In some embodiments, a microelectronic assembly may include a package substrate; a stiffener having a surface, wherein the stiffener includes a cavity and a conductive pathway between the cavity and the surface of the stiffener, and wherein the stiffener is coupled to the package substrate such that the surface of the stiffener is between the cavity and the package substrate; and an electrical component, wherein the electrical component is embedded in the cavity and is electrically coupled to the package substrate via the conductive pathway.

### BACKGROUND

Package substrates in integrated circuit (IC) packages are traditionally used to route electrical connections between a die and a circuit board. Dies and other functional components and elements may be disposed on a face of a package substrate. For example, stiffeners may be disposed on a face of the package substrate along with the die to prevent warpage, which is especially useful in coreless, ultra-thin core (UTC), and wafer level integrated circuit products.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a side, cross-sectional view of a microelectronic assembly, in accordance with various embodiments.

FIG. 2A is a side, cross-sectional view of a portion of an exemplary stiffener, in accordance with various embodiments.

FIG. 2B is a magnified view of a part of the stiffener of FIG. 2A, in accordance with various embodiments.

FIG. 3A is a side, cross-sectional view of a portion of an exemplary stiffener, in accordance with various embodiments.

FIG. 3B is a magnified view of a part of the stiffener of FIG. 3A, in accordance with various embodiments.

FIG. 4 is a side, cross-sectional view of a portion of an exemplary stiffener, in accordance with various embodiments.

FIG. 5A is a schematic illustration of a top plane view of an example microelectronic assembly, in accordance with various embodiments.

FIG. 5B is a simplified schematic illustration of a cross-sectional side view along the A-A′ line of the microelectronic assembly of FIG. 5A.

FIG. 6 is a flow diagram of an example method of manufacturing a microelectronic assembly, in accordance with various embodiments.

FIG. 7 is a flow diagram of another example method of manufacturing a microelectronic assembly, in accordance with various embodiments.

FIG. 8 is a side, cross-sectional view of an exemplary stiffener, in accordance with various embodiments.

FIG. 9 is a block diagram of an example computing device that may include any of the embodiments of the microelectronic assemblies disclosed herein.

### DETAILED DESCRIPTION

Disclosed herein are microelectronic assemblies, as well as related apparatuses and methods. For example, in some embodiments, a microelectronic assembly may include a package substrate; a stiffener having a surface, wherein the stiffener includes a cavity and a conductive pathway between the cavity and the surface of the stiffener, and wherein the stiffener is coupled to the package substrate such that the surface of the stiffener is between the cavity and the package substrate; and an electrical component, wherein the electrical component is embedded in the cavity and is electrically coupled to the package substrate via the conductive pathway.

Providing a reliable power supply to an IC package, including a multi-die IC package, is challenging due to the increasingly small size of such IC packages. Various ones of the embodiments disclosed herein may help achieve improved performance of IC packages, with a reliable power supply, relative to conventional approaches. The microelectronic assemblies disclosed herein may be particularly advantageous for small and low-profile applications in computers, tablets, industrial robots, and consumer electronics (e.g., wearable devices).

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die,” and “a component” and “an electrical component.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

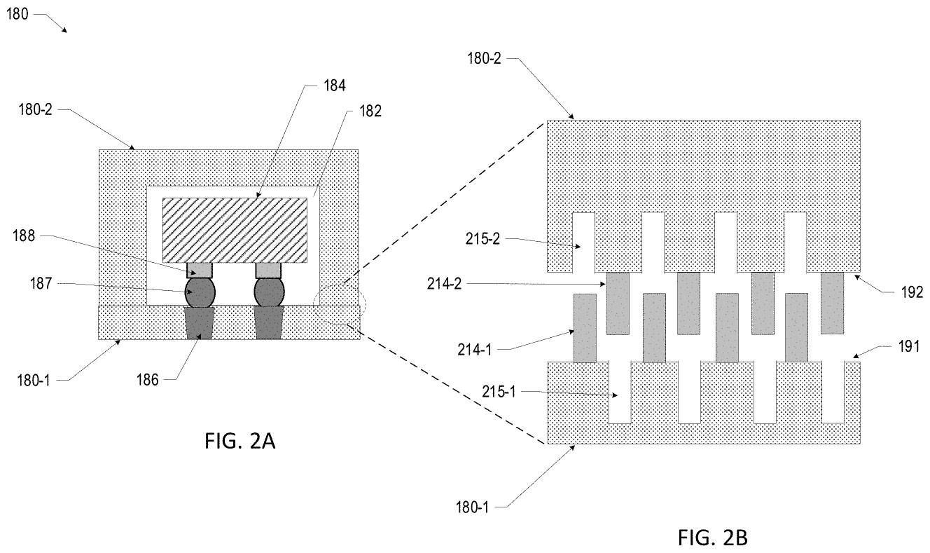

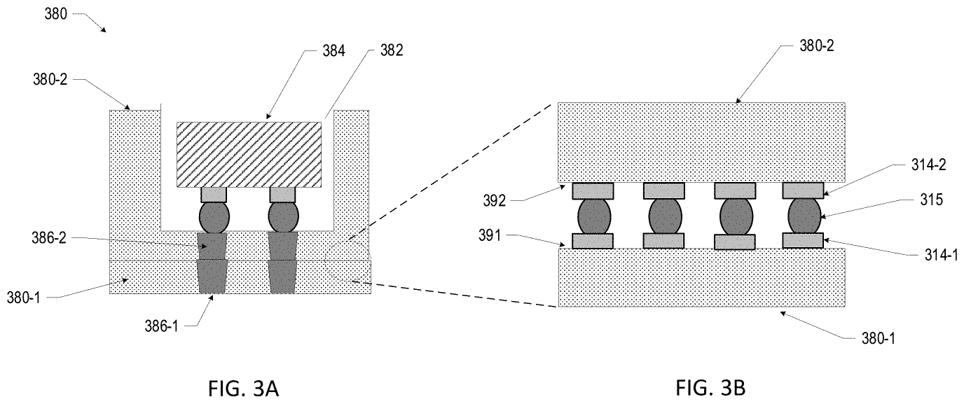

When used to describe a range of dimensions, the phrase “between X and V” represents a range that includes X and Y. For convenience, the phrase “FIG. 2” may be used to refer to the collection of drawings of FIGS. 2A-2B, the phrase “FIG. 3” may be used to refer to the collection of drawings of FIGS. 3A-3B, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

Electrical components disposed on the surfaces of a package substrate may be critical for IC package performance and efficiency. For example, voltage regulators are commonly used for providing electrical power with a stable voltage in IC devices. Typically, a voltage regulator is composed of a variety of components, including an inductor, which are traditionally disposed on a surface of a circuit board. Disposing an inductor of a voltage regulator on a surface of a package substrate along with dies and other functional components may be especially useful in reducing the size of an IC device. To reduce the z-height of an IC package, a package substrate may be made thinner but thinner substrates may be more likely to warp. To address substrate warpage, a stiffener may be included on the die side of the package substrate. A die typically does not cover the entire surface area of the package substrate. Additional electrical components, such as capacitors, inductors, and other dies may be included on the surface area of the package substrate. A stiffener may be included on the surface area of the package substrate and may cover areas of the package substrate that are not covered by the die. A stiffener may be designed to provide stability to a package substrate. Improved stability may be particularly advantageous in situations where the package substrate is a thin core or coreless substrate. A stiffener may be fabricated from materials that exhibit desirable mechanical strength and some resistance to corrosion. Attaching a stiffener to the first surface of the package substrate to prevent warpage may further reduce the ability to couple components adjacent to a die. The use of a stiffener with cavities for embedding electrical components, such as an inductor, increases available area for coupling components on the surface of the package substrate. Moreover, by increasing the available space on a first surface of a package substrate, the need to place components on a second surface of the package substrate and/or on the circuit board may be eliminated, and the overall size of the package may be reduced. Further, by eliminating components from a second surface of the package substrate, conductive contacts may be populated across the entire package for improved device performance/functionality through increased interconnect input/output (I/O) density and/or reduced form factor.

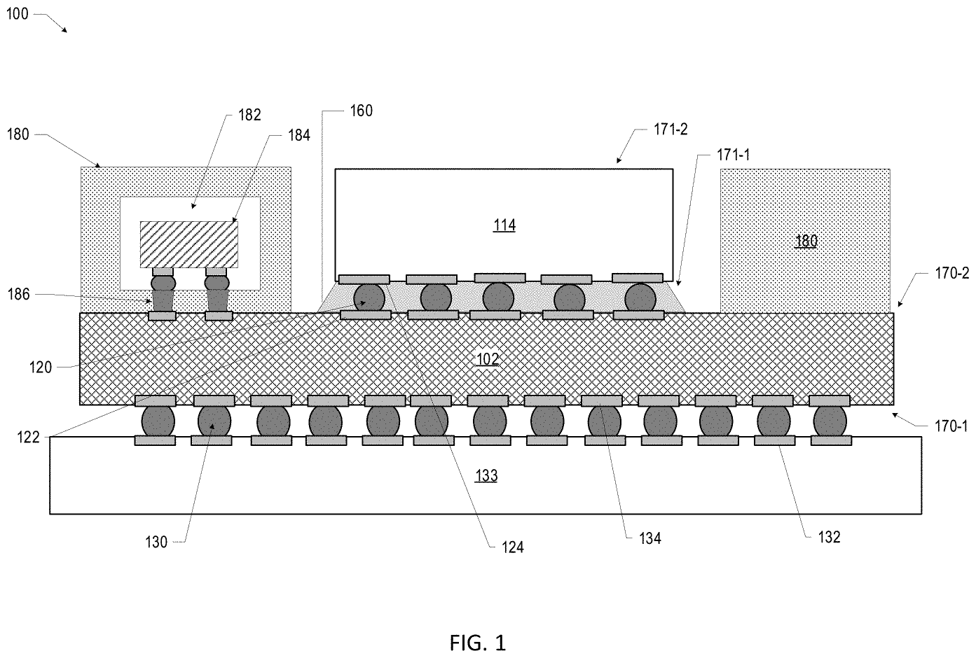

FIG. 1 is a side, cross-sectional view of a microelectronic assembly 100, in accordance with various embodiments. The microelectronic assembly 100 may include a package substrate 102 with a die 114 and a stiffener 180 disposed thereon. In particular, the stiffener 180 may include a cavity 182 having an electrical component 184 embedded therein and may include one or more conductive pathways 186 through the stiffener 180. The package substrate 102 may have first conductive contacts 134 on a first surface 170-1 and second conductive contacts 122 on an opposing second surface 170-2. The embedded electrical component 184 may be electrically coupled to the conductive contacts 122 on the second surface 170-2 of the package substrate 102 via the conductive pathways 186 through the stiffener 180. The die 114 may have a first surface 171-1 having conductive contacts 124 and an opposing second surface 171-2. The conductive contacts 124 on the first surface 171-1 of the die 114 may be coupled to the conductive contacts 122 on the second surface 170-2 of the package substrate 102 via first level interconnects 120. In some embodiments, the first level interconnects 120 may include solder bumps or balls (as illustrated in FIG. 1); in other embodiments, the first level interconnects 120 may include wirebonds or any other suitable interconnect. The die 114 may be electrically coupled to the embedded component 184 via conductive pathways in the package substrate 102 (not shown). In some embodiments, the package substrate 102 may be a coreless substrate, a UTC substrate, a wafer level packaging, or any other suitable package designed to minimize z-height, as is known in the art.

The stiffener 180 may be made from any suitable non-conductive material, such as, ceramic, ceramic and metal, or silicon carbide and diamond, and made using any suitable technique, such as molding or sintering. The stiffener 180 may have any suitable dimensions and shape. For example, the dimensions of the stiffener 180 may depend on the surface area (e.g., the x-y dimensions of the package substrate) and on the available surface area (e.g., the die-attach area versus the non-die-attach area on the surface of the package substrate). The stiffener 180 may have any suitable thickness. The thickness of the stiffener may depend on the type of material or materials used to mitigate warpage, and may further depend on the size of the embedded electrical components 184. In some embodiments, the thickness of the stiffener may range from 50 microns (um) to 1600 um. In some embodiments, the thickness of the stiffener may range from 100 um to 400 um In some embodiments, the stiffener may have a protective layer or other layer deposited on the top surface to, for example, facilitate thermal dissipation. In some embodiments, the stiffener 180 may take the shape of a frame or outer ring along the perimeter of the package substrate 102 on the outside of die 114. In some embodiments, for example, the stiffener 180 may be L-shaped, I-shaped, C-shaped, or rectangular. In some embodiments, a package substrate may include a plurality of stiffeners. For example, a package substrate may include two L-shaped stiffeners arranged to form a non-continuous frame around the perimeter of the package substrate. The stiffener 180 may be attached or secured to the package substrate using any suitable means, such as, for example, adhesive, conductive adhesive, metal-to-metal connections (e.g., copper-to-copper connections, or aluminum-to-aluminum connections, and other metals), solder paste materials, or solder balls. In some embodiments, contact pads may be formed on the package substrate to align with the conductive pathways 186 in the stiffener. In some embodiments, a conductive adhesive may be disposed, or solder balls formed, between the conductive pathways 186 and the conductive pads on the package substrate. In some embodiments, a solder resist may be disposed on the package substrate and openings may be formed through the solder resist and filled with conductive material to electrically connect the conductive pathways in the stiffener to the conductive routing on the package substrate. The stiffener 180 may have more than one means of attachment to the package substrate, for example, conductive adhesive may electrically couple the stiffener 180 via the conductive pathways 186 to the package substrate 102 and a non-conductive adhesive, such as epoxy or silicon, may attach the stiffener to the package substrate in areas of the stiffener without the conductive pathways. In another example, an anisotropic conductive adhesive may be dispensed or printed on the contact pads on the surface of the package substrate that align with the conductive pathways in the stiffener and non-conductive adhesive may be dispensed in the non-pad areas. The adhesives may be cured, for example, under high pressure. In one embodiment, an anisotropic conductive adhesive may include fillers. A representative example of a filler is a conductive material-coated (e.g., metal-coated) elastomeric ball (e.g., gold or silver or silver/gold coated balls) or similar shaped materials that are compressible under bonding pressure. Fillers, such as elastomeric balls, may provide improved tolerance to process variations and improved contact in electrical performance in addition to providing a conductive pad between the conductive element and the package substrate. In another embodiment, the filler is a gold, silver, or silver/gold coated copper ball may be attached to the package substrate using conductive adhesive, or by any other suitable means, including, but not limited to, solder ball reflow process, among others. In some embodiments, the stiffener 180 may be planar and substantially parallel to the surface of the package substrate. In some embodiments, the stiffener 180 may be continuous and may cover the entire non-die-attach area (e.g., the exposed surface area of the package substrate that surrounds the one or more dies). In some embodiments, the stiffener 180 may be more than one stiffener. In some embodiments, the stiffener 180 whether a single stiffener or multiple stiffeners may cover only a portion of the non-die-attach area (e.g., the exposed surface area of the package substrate that surrounds the one or more dies, where dies may not be attached).

The cavity 182 may have any suitable dimensions for housing one or more electrical components while providing mechanical support to the IC package. The cavity 182 may be formed using any suitable technique, for example, by sintering or molding, among others. In some embodiments, the cavity 182 may include a mold material or an underfill material surrounding the electrical component 184. In some embodiments, the cavity size (i.e., length times width) may range from 125 um by 125 um to 45 mm by 3 mm, including any and all dimensions in between. In some embodiments, the cavity depth may range from 150 um to 780 um, and may vary depending on the thickness of the stiffener. The cavity may be positioned in any suitable location on the stiffener, and may be adjusted to match component placement and electrical connections on the package substrate. A cavity may have any suitable electrical connections for coupling embedded components to the conductive pathways 186 in the stiffener 180, including, for example, metal-to-metal connections, solder or conductive adhesive. An electrical connection for connecting an embedded component to the conductive pathways may be positioned at any suitable location within the cavity, including on the bottom surface of the cavity and/or on a side wall of the cavity

The conductive pathways 186 in the stiffener 180 may be made of any suitable conductive material or materials, such as copper or a copper alloy. The conductive pathways 186 may be formed using any suitable technique and may be formed during stiffener manufacturing. For example, a ceramic stiffener having vias as the conductive pathways may be formed by blanking, via punching, via filling, collating, laminating, pre-cutting, and co-firing. The conductive pathways 186 may allow power, ground, and other electrical signals to move between the component 184 and the package substrate 102. For example, the component 184 may include an inductor and the electrical connection between the inductor and the package substrate may be associated with a voltage output rail.

A component 184 may have any suitable dimensions, and component dimensions may vary according to application, construction, and design requirements (e.g., specific z-height dimension) of an IC package. In some embodiments, a component may have a length-dimension ranging from 150 um to 600 um and a width-dimension ranging from 100 um to 2 mm. In some embodiments, the embedded electrical component 184 is a passive component, including a resistor, a capacitor, an inductor, or a chip-type passive component, such as silicon capacitor or a silicon metal-in-metal (MIM) capacitor. In some embodiments, the embedded component 184 may include a magnetic inductor array (MIA) for voltage regulation.

The microelectronic assembly 100 may further include a circuit board 133. The first conductive contacts 134 on the first surface 170-1 of the package substrate 102 may be coupled to conductive contacts 132 on a surface of the circuit board 133 via second level interconnects 130. In some embodiments, the second level interconnects 130 may include solder balls (as illustrated in FIG. 1) for a ball grid array (BGA) coupling; in other embodiments, the second level interconnects 130 may include solder paste contacts to provide land grid array (LGA) interconnects, or any other suitable interconnect. In some embodiments, the circuit board 133 may include one or more components disposed thereon (not shown). The circuit board 133 may include conductive pathways that allow power, ground, and other electrical signals to move between the circuit board 133 and the package substrate 102 as well as between the circuit board 133 and the die 114 or the embedded component 184, as known in the art.

Although FIG. 1 shows a single cavity 182 having a single embedded component 184, the stiffener 180 may include multiple cavities 182 and multiple embedded components 184. Further, a single cavity 182 may include multiple embedded components 184. The package substrate 102 may also include conductive pathways (not shown) that may couple the die 114 to the embedded component 184, and conductive pathways (not shown) that may couple the die 114 to the circuit board 133 (e.g., via the first level interconnects 120 and the second level interconnects 130). Any suitable arrangement of conductive pathways may couple the die 114, the component 184, and the circuit board 133, as desired.

Although a single die 114 is illustrated in FIG. 1, this is simply an example, and the microelectronic assembly 100 may include one or more dies 114. The dies may perform any suitable functionality, and may include processing devices, memory, communications devices, sensors, or any other computing components or circuitry. For example, the dies may include a central processing unit (CPU), a platform controller hub (PCH), a dynamic random access memory (DRAM), a graphic processing unit (GPU), and a field programmable gate array (FPGA). In some embodiments, an underfill material 160 may be disposed between the die 114 and the second surface 170-2 of the package substrate 102. In some embodiments, an overmold or fill material (not shown) may be disposed around the die 114 and in contact with the second surface 170-2 of the package substrate 102.

Although FIG. 1 illustrates a single IC package (e.g., package substrate 102 with die 114) disposed on the circuit board 133, this is simply for ease of illustration and multiple IC packages may be disposed on the circuit board 133. In some embodiments, the circuit board 133 may be a printed circuit board (PCB) (e.g., a motherboard). In some embodiments, the circuit board 133 may be another IC package, and the microelectronic assembly 100 may be a package-on-package structure. In some embodiments, the circuit board 133 may be an interposer, and the microelectronic assembly 100 may be a package-on-interposer structure.

FIG. 2A is a side, cross-sectional view of a portion of an exemplary stiffener, in accordance with various embodiments. FIG. 2B is a magnified view of a part of the stiffener of FIG. 2A, in accordance with various embodiments. As shown in FIG. 2, the stiffener 180 may include a first portion 180-1, or a base, and a second portion 180-2, or a body. The first portion 180-1 may include conductive pathways 186. The second portion 180-2 may include a cavity 182 for embedding or housing a component 184 where the cavity is on a bottom surface of the second portion 180-2. The component 184 may include conductive contacts 188 on a surface, such as solder or conductive pads. The conductive contacts 188 on the surface of the electrical component 184 may be electrically coupled to the one or more conductive pathways 186 in the first portion 180-1 of the stiffener by an interconnect 187, such as a solder bump, conductive adhesive, or metal-to-metal connections. In some embodiments, the component 184 may be attached to the first portion 180-1 using surface mount technology (SMT).

The second portion 180-2 of the stiffener 180 may be placed on the first portion 180-1 of the stiffener 180 with the cavity 182 facing the first portion 180-1 such that the component 184 is within the cavity 182. The first portion 180-1 of the stiffener 180 may be attached to the second portion 180-2 of the stiffener 180 using any suitable technique, including, as shown in FIG. 2B, interdigitated fingers or teeth, and other similar structures. For example, the first portion 180-1 of the stiffener 180 may include a plurality of projections 214-1 and a plurality of recesses 215-1 on a surface 191 and the second portion 180-2 of the stiffener 180 may include a plurality of projections 214-2 and a plurality of recesses 215-2 on a surface 192. The first portion 180-1 and second portion 180-2 of the stiffener 180 may be positioned to align the plurality projections 214-1 of the first portion 180-1 with the plurality of recesses 215-2 of the second portion 180-2 such that the plurality of projections fit into the plurality of recesses to connect the first portion 180-1 to the second portion 180-2. The assembled stiffener 180 may be attached to a package substrate using any suitable technique as described above with reference to FIG. 1.

FIG. 3A is a side, cross-sectional view of a portion of an exemplary stiffener, in accordance with various embodiments. FIG. 3B is a magnified view of a part of the stiffener of FIG. 3A, in accordance with various embodiments. As shown in FIG. 3, the stiffener 380 may include a first portion 380-1 and a second portion 380-2. The first portion 380-1 may include conductive pathways 386-1. The second portion 380-2 may include a cavity 382 for embedding or housing a component 384 where the cavity is on a top surface of the second portion 380-2. The second portion 380-2 may include conductive pathways 386-2 through a bottom surface that electrically couple to the conductive pathways 386-1 in the first portion 380-1 when the stiffener 380 is assembled. The component 384 may be electrically coupled to the conductive pathways 386-2 in the second portion 380-2 of the stiffener 380. The second portion 380-2 of the stiffener 380 may be placed on the first portion 380-1 of the stiffener 380 with the cavity 382 facing away from the first portion 380-1. The first portion 380-1 of the stiffener 380 may be attached to the second portion 380-2 of the stiffener 380 using any suitable technique, including adhesive, epoxy, or, as shown in FIG. 3B, solder. For example, the first portion 380-1 may include a plurality of conductive contacts 314-1 on a surface 391 and the second portion 380-2 may include a plurality of conductive contacts 314-2 on a surface 392. The first portion 380-1 and second portion 380-2 may be positioned to align the plurality of conductive contacts 314 and interconnects between the plurality of conductive contacts 314 may be formed using solder 315. The assembled stiffener 380 may be attached to a package substrate using any suitable technique as described above with reference to FIG. 1. In some embodiments, the stiffener may further include a lid (not shown) on the top surface of the cavity to cover the cavity opening and/or provide mechanical support to the stiffener. In some embodiments, the lid may extend to cover more than the cavity opening and, in some other embodiments, may extend to cover the top surface of the stiffener.

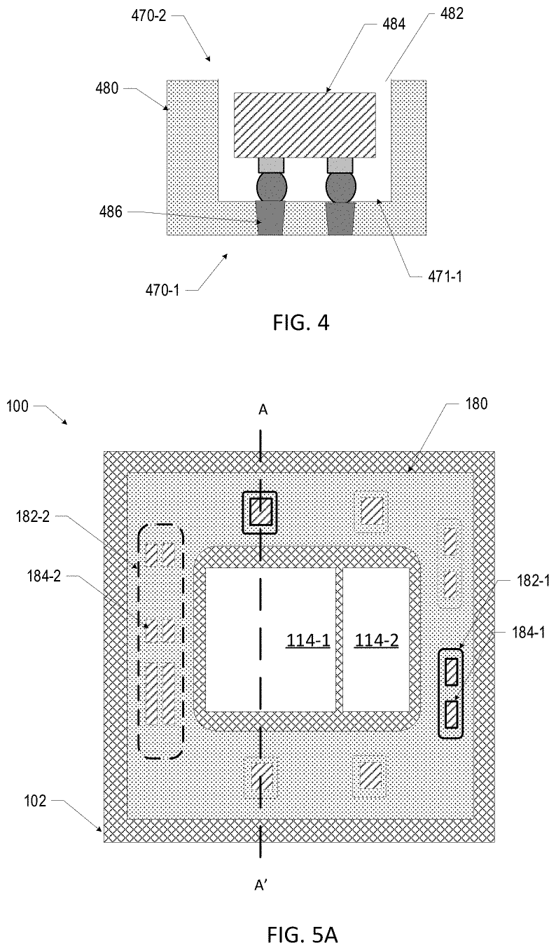

FIG. 4 is a side, cross-sectional view of a portion of an exemplary stiffener, in accordance with various embodiments. As shown in FIG. 4, the stiffener 480 may have a bottom surface 470-1 and an opposing top surface 470-2. In particular, the stiffener 480 may include a cavity 482 on a top surface 470-2 of the stiffener 480 and conductive pathways 486 between a bottom surface 471-1 of the cavity 482 and a bottom surface 470-1 of the stiffener 480. The stiffener 480 may further include a component 484 embedded in the cavity and electrically coupled to the conductive pathways 486 in the stiffener 480. The stiffener 480 may be attached to a package substrate via the conductive pathways 486 on the bottom surface 470-1 of the stiffener using any suitable technique as described above with reference to FIG. 1.

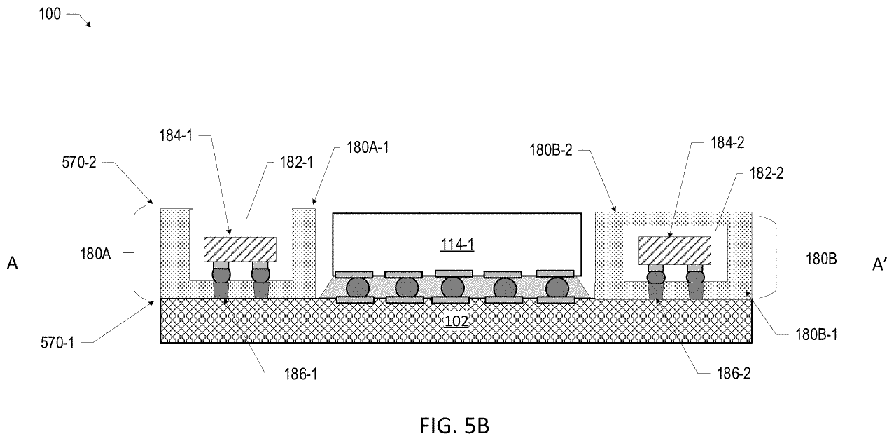

FIG. 5A is a schematic illustration of a top plane view of an example microelectronic assembly, in accordance with various embodiments. FIG. 5A shows a microelectronic assembly 100 having package substrate 102 with two dies 114-1, 114-2 and a stiffener 180 attached to a first surface of the package substrate. Although only two dies are shown, a plurality of dies may be attached to the package substrate. The dies 114-1, 114-2 may be any type of dies, including, for example, a CPU, a PCH, DRAM, a GPU, and an FPGA, and may be electrically connected to the package substrate 102 via any suitable means, for example, controlled collapsed chip connection (C4) bumps, among others. Stiffener 180 may include one or more cavities 182, which may have one or more components 184 embedded therein. The cavities 182 may be formed on a top surface and/or a bottom surface of the stiffener by any suitable means, including, for example, sintering and molding, among others. The sold lines, which form the cavities 182-1 and the components 184-1 in FIG. 5A, indicated that the cavity is formed on a top surface of the stiffener 180 and that the structures are located on the topside of the stiffener 180 and may be visible from the top plane view. The dotted lines, which form the cavities 182-2 and components 184-2 in FIG. 5A, indicate that the cavity is formed on a bottom surface of the stiffener and that structures are located on the underside of the stiffener 180 and may not be visible from the top plane view. Although FIG. 5A shows a particular number and arrangement of cavities and embedded components, a stiffener may have any suitable number and arrangement of cavities and embedded components. In some embodiments, a stiffener may include one or more cavities formed on a top surface, where the cavities are open and without a top piece or lid. In some embodiments, a stiffener may include one or more cavities formed on an underside, where the one or more cavities are formed on a bottom surface such that the cavities are enclosed (e.g., have a top piece and a bottom piece). In some embodiments, a stiffener may include a combination, where a first cavity may be formed on a top surface and a second cavity may be formed on a bottom surface (e.g., as shown in FIG. 5B).

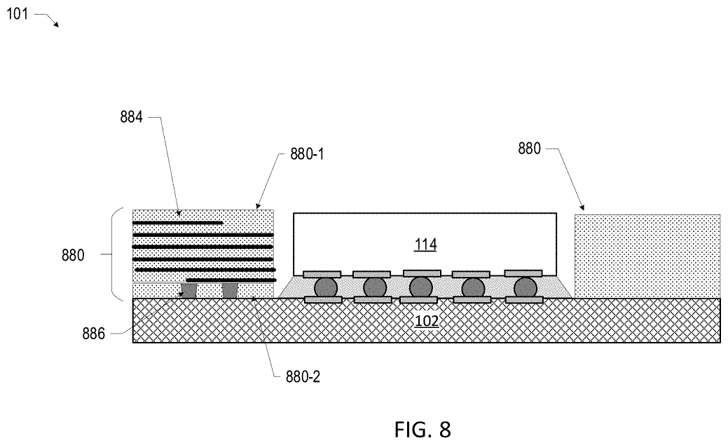

FIG. 5B is a simplified schematic illustration of a cross-sectional side view along the A-A′ line of the microelectronic assembly of FIG. 5A. FIG. 5B is a simplified illustration of a cross-sectional view of microelectronic assembly 100 showing the package substrate 102, the die 114-1, the stiffener 180 having two embedded components 184-1, 184-2, and conductive pathways 186-1, 186-2 through the stiffener. The two embedded components 184-1, 184-2 are electrically coupled to the package substrate 102 via the conductive pathways 186-1, 186-2, respectively. As shown in FIG. 5B, the stiffener 180 may have a heterogeneous structure, such that the stiffener may have a different structure in different segments (e.g., 180A and 180B). For example, in a first segment 180A, the stiffener may be formed from a single portion 180A-1, and, in a second segment 180B, the stiffener may be formed from a first portion 180B-1 and a second portion 180B-2. In particular, the stiffener 180 having a first surface 570-1 and an opposing second surface 570-2 may include a first segment 180A having a first cavity 182-1 on the second surface 570-2, and a second segment 180B having a second cavity 182-2 on the first surface 570-1. The first cavity 182-1 may include a first component 184-1 having conductive contacts, where the first component 184-1 may be electrically coupled to the conductive pathways 186-1 in the stiffener 180A-1 that are formed between the bottom surface of the cavity and the first surface 570-1 of the stiffener 180A-1. The second cavity 182-2 may include a second component 184-2 having conductive contacts, where the second component 184-2 may be electrically coupled to the package substrate 102 via the conductive pathways 186-2 formed in the first portion 180B-1 of the stiffener (e.g., as described above with reference to FIGS. 3 and 4). As shown in FIG. 5B, the stiffener in the second segment 180B may include a first portion 180B-1 and a second portion 180B-2 where the conductive pathways 186-2 may be formed in the first portion 180B-1 and the cavity 182-2 may be formed in the second portion 180B-2. The component 184-2 may be coupled to the conductive pathways 186-2 in the first portion 180B-1, then the first portion 180B-1 may be attached to the second portion 180B-2 as described above with reference to FIGS. 3 and 4. The assembled stiffener 180 having the first segment 180A and second segment 180B may be attached to the package substrate using any suitable techniques as described above with reference to FIG. 1. Although FIG. 5B shows a first segment 180A including a single portion of the stiffener and a second segment 180B including a first portion and a second portion of the stiffener, a stiffener may have any number of segments with any number of portions in any of the embodiments disclosed herein, for example, as shown or described in FIG. 2, FIG. 3, FIG. 4, and FIG. 8.

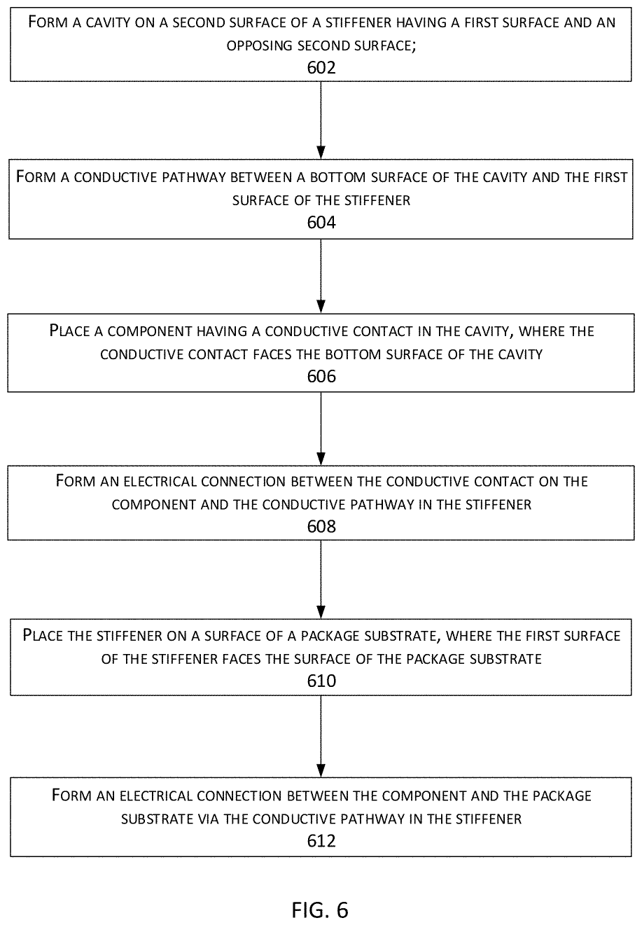

FIG. 6 is a flow diagram of an example method of manufacturing a package substrate including a stiffener having a cavity for embedding a component and having a conductive pathway for connecting the embedded component to the package substrate, in accordance with various embodiments. At 602, a cavity may be formed on a second surface of a stiffener having a first surface and an opposing second surface. In some embodiments, the cavity may be formed when the stiffener is formed, for example, by sintering. In some embodiments, the cavity may be formed after the stiffener is formed, for example, by cutting. At 604, a conductive pathway may be formed between the bottom surface of the cavity and the first surface of the stiffener. In some embodiments, the conductive pathway may be formed by molding or drilling an opening, then filling the opening with conductive material, such as copper. At 606, a component having a conductive contact on a surface may be placed within the cavity, where the conductive contact of the component faces the bottom surface of the cavity and may align with the conductive pathway at the bottom of the cavity. The component may be place using any suitable technique, for example, using a pick and place process. At 608, an electrical connection may be formed between the component in the cavity and the conductive pathway in the stiffener. For example, the electrical connection may be formed by a solder reflow process or a metal-to-metal connection. In some embodiments, a lid may be placed on the top surface of the cavity to cover the cavity opening. At 610, the stiffener may be placed on the package substrate with the first surface of the stiffener facing a surface of the package substrate such that electrical connections on the stiffener (i.e., conductive pathway on the first surface of the stiffener) align with the electrical connections on the package substrate. At 612, an electrical connection may be formed between the stiffener and the package substrate, as well as the component via the conductive pathway in the stiffener. The finished substrate may be a single package substrate or may be a repeating unit that may undergo a singulation process in which each unit is separated from one another to create a single package substrate. Singulated substrates may be any suitable size and any suitable thickness; typically, substrates may range from 12 mm by 12 mm to 50 mm by 50 mm in size, and between 100 um and 2000 um in thickness.

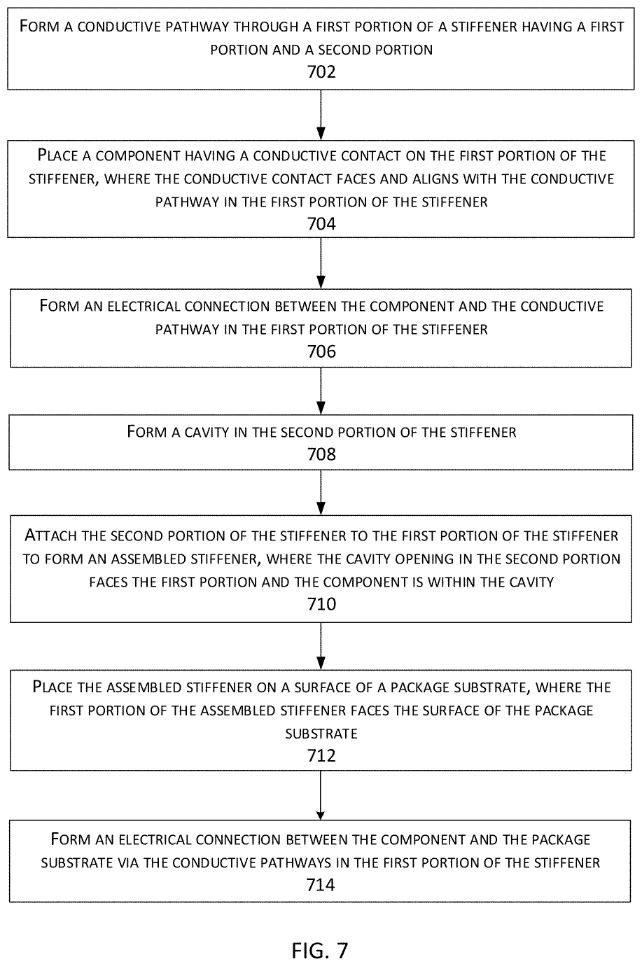

FIG. 7 is a flow diagram of another example method of manufacturing a package substrate including a stiffener having a cavity for embedding a component and having conductive pathways for connecting the embedded component to the package substrate, in accordance with various embodiments. At 702, a conductive pathway may be formed in a first portion of a stiffener having a first portion and a second portion. At 704, a component having a conductive contact on a surface may be placed on the first portion of the stiffener, where the conductive contact on the component faces and aligns with the conductive pathway in the first portion of the stiffener. At 706, an electrical connection may be formed between the component in the cavity and the conductive pathway in the first portion of the stiffener. At 708, a cavity may be formed in the second portion of the stiffener. At 710, the first portion and second portion of the stiffener may be attached to form an assembled stiffener, where the cavity opening in the second portion faces the first portion and the component is within the cavity. The first portion and second portion may be attached using any suitable technique, such as the techniques described above with reference to FIGS. 2 and 3. In some embodiments, the first portion and the second portion of the stiffener may be attached to form an assembled stiffener subsequent to the first portion has been placed and attached to the package substrate. At 712, the assembled stiffener may be placed on a surface of a package substrate, where the first portion of the assembled stiffener faces the surface of the package substrate. At 714, an electrical connection may be formed between the stiffener and the package substrate, as well as the component via the conductive pathway in the stiffener. The finished substrate may be a single package substrate or may be a repeating unit that may undergo a singulation process in which each unit is separated from one another to create a single package substrate.

FIG. 8 is a side, cross-sectional view of an exemplary stiffener, in accordance with various embodiments. The microelectronic assembly 101 may include a package substrate 102 with a die 114 and a stiffener 880 disposed thereon. In particular, the stiffener 880 may include an electrical component 884 embedded therein, where the electrical component 884 may be integrated or formed in the stiffener 880. In some embodiments, the embedded electrical component 884 may include a resistor, a capacitor, or an inductor. In some embodiments, the embedded electrical component 884 may include an air core inductor for voltage regulation. In some embodiments, the air core inductor may have a hollow core (e.g., the center of the air core inductor may be filled with air). In some embodiments, the air core inductor may have a core filled with a material, such as dielectric material, mold material, or the same material as the stiffener, for example, ceramic. The embedded electrical component 884 may be electrically coupled to the package substrate 102 via the conductive pathways 886 through the stiffener 880. The stiffener 880 and the conductive pathways 886 may be formed using any suitable technique and any suitable material, as described above with reference to FIG. 1.

In some embodiments, as shown in FIG. 8, the stiffener 880 may include a first portion 880-1, or a base, and a second portion 880-2, or a body. The first portion 880-1 may include conductive pathways 886. The second portion 880-2 may include an embedded electrical component 884. The electrical component 884 may include conductive contacts (not shown) on a surface of the second portion 880-2, such as solder or conductive pads. The conductive contacts may be electrically coupled to the one or more conductive pathways 886 in the first portion 880-1 of the stiffener by an interconnect, such as a solder bump, conductive adhesive, or a metal-to-metal connection. The first portion 880-1 of the stiffener 880 may be attached to the second portion 880-2 of the stiffener 880 using any suitable technique, including, as shown described above with reference to FIG. 2, interdigitated fingers or teeth, and other similar structures.

In some embodiments, the stiffener 880 may be single structure (e.g., not formed from two portions) (not shown), and may include an electrical component 884 and conductive pathways 886 integrated in the stiffener 880. In some embodiments, the electrical component 884 and conductive pathways may be formed when the stiffener is manufactured.

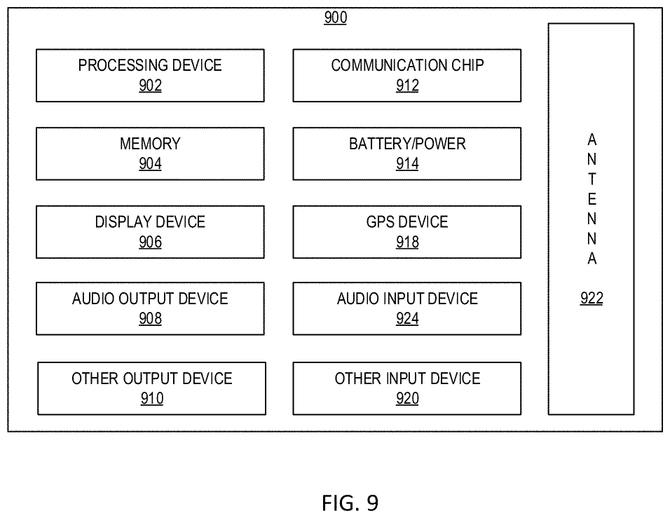

The package substrates disclosed herein may be included in any suitable electronic device. FIG. 9 is a block diagram of an example computing device 900 that may include one or more of the package substrates disclosed herein. For example, any suitable ones of the components of the computing device 900 may include, or be included in, an IC package having a package substrate with a conductive element having a cavity for a passive component and where the conductive element is electrically connected to the passive component, in accordance with any of the embodiments disclosed herein. A number of components are illustrated in FIG. 9 as included in the computing device 900, but any one or more of these components may be omitted or duplicated, as suitable for the application. In some embodiments, some or all of the components included in the computing device 900 may be attached to one or more motherboards. In some embodiments, some or all of these components are fabricated onto a single system-on-a-chip (SoC) die.

Additionally, in various embodiments, the computing device 900 may include interface circuitry for coupling to the one or more components. For example, the computing device 900 may not include a display device 906, but may include display device interface circuitry (e.g., a connector and driver circuitry) to which a display device 906 may be coupled. In another set of examples, the computing device 900 may not include an audio input device 924 or an audio output device 908, but may include audio input or output device interface circuitry (e.g., connectors and supporting circuitry) to which an audio input device 924 or audio output device 908 may be coupled.

The computing device 900 may include a processing device 902 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 902 may include one or more digital signal processors (DSPs), application-specific integrated circuits (ASICs), CPUs, GPUs, cryptoprocessors (specialized processors that execute cryptographic algorithms within hardware), server processors, or any other suitable processing devices. The computing device 900 may include a memory 904, which may itself include one or more memory devices such as volatile memory (e.g., DRAM), nonvolatile memory (e.g., read-only memory (ROM)), flash memory, solid state memory, and/or a hard drive. In some embodiments, the memory 904 may include memory that shares a die with the processing device 902. This memory may be used as cache memory and may include embedded DRAM (eDRAM) or spin transfer torque magnetic random access memory (STT-M RAM).

In some embodiments, the computing device 900 may include a communication chip 912 (e.g., one or more communication chips). For example, the communication chip 912 may be configured for managing wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other embodiments. The computing device 900 may include an antenna 922 to facilitate wireless communications and/or to receive other wireless communications (such as AM or FM radio transmissions).

In some embodiments, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some embodiments, a first communication chip 912 may be dedicated to wireless communications, and a second communication chip 912 may be dedicated to wired communications.

The computing device 900 may include battery/power circuitry 914. The battery/power circuitry 914 may include one or more energy storage devices (e.g., batteries or capacitors) and/or circuitry for coupling components of the computing device 900 to an energy source separate from the computing device 900 (e.g., AC line power).

The computing device 900 may include a display device 906 (or corresponding interface circuitry, as discussed above). The display device 906 may include any visual indicators, such as a heads-up display, a computer monitor, a projector, a touchscreen display, a liquid crystal display (LCD), a light-emitting diode display, or a flat panel display, for example.

The computing device 900 may include an audio output device 908 (or corresponding interface circuitry, as discussed above). The audio output device 908 may include any device that generates an audible indicator, such as speakers, headsets, or earbuds, for example.

The computing device 900 may include an audio input device 924 (or corresponding interface circuitry, as discussed above). The audio input device 924 may include any device that generates a signal representative of a sound, such as microphones, microphone arrays, or digital instruments (e.g., instruments having a musical instrument digital interface (MIDI) output).

The computing device 900 may include a GPS device 918 (or corresponding interface circuitry, as discussed above). The GPS device 918 may be in communication with a satellite-based system and may receive a location of the computing device 900, as known in the art.

The computing device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The computing device 900 may include an other input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 900 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 900 may be any other electronic device that processes data.

The following examples pertain to further embodiments. The various features of the different embodiments may be variously combined with some features included and others excluded to suit a variety of different applications.

Example 1 is a microelectronic assembly, including: a package substrate; a stiffener having a surface, wherein the stiffener includes a cavity and a conductive pathway between the cavity and the surface of the stiffener, and wherein the stiffener is coupled to the package substrate such that the surface of the stiffener is between the cavity and the package substrate; and an electrical component, wherein the electrical component is embedded in the cavity and is electrically coupled to the package substrate via the conductive pathway.

Example 2 may include the subject matter of Example 1, and may further specify that the electrical component is a magnetic inductor array for voltage regulation.

Example 3 may include the subject matter of Example 2, and may further specify that an electrical connection between the magnetic inductor array and the package substrate is coupled to a voltage output rail.

Example 4 may include the subject matter of Example 1, and may further specify that the stiffener includes ceramic.

Example 5 may include the subject matter of Example 1, and may further specify that the stiffener includes a first portion having first fingers and a second portion having second fingers that are interdigitated with the first fingers, and wherein the first portion is attached to the second portion by interconnecting the first fingers and the second fingers.

Example 6 may include the subject matter of Example 1, and may further specify that the stiffener includes a first portion having a first conductive contact and a second portion having a second conductive contact, and wherein the first portion is attached to the second portion by electrically connecting the first conductive contact and the second conductive contact.

Example 7 may include the subject matter of Example 6, and may further specify that the first conductive contact is electrically connected to the second conductive contact by solder.

Example 8 may include the subject matter of Example 6, and may further specify that the first conductive contact is electrically connected to the second conductive contact by a metal-to-metal connection.

Example 9 may include the subject matter of Example 1, and may further specify that the electrical component is a first electrical component, the conductive pathway in the stiffener is a first conductive pathway, and the microelectronic assembly further includes: a second conductive pathway in the stiffener, where the second conductive pathway is between the cavity and the surface of the stiffener; and a second electrical component, wherein the second electrical component is embedded in the cavity and is electrically coupled to the package substrate via the second conductive pathway.

Example 10 may include the subject matter of Example 1, and may further specify that the electrical component is a first electrical component and wherein the cavity is a first cavity, and may further include: a second cavity in the stiffener having a second conductive pathway, where the second conductive pathway is between the second cavity and the surface of the stiffener; and a second electrical component, wherein the second electrical component is embedded in the second cavity and is electrically coupled to the package substrate via the second conductive pathway.

Example 11 may include the subject matter of Example 1, and may further specify that the stiffener is to mitigate warpage of the microelectronic assembly.

Example 12 may include the subject matter of Example 1, and may further include: a die coupled to the surface of the package substrate.

Example 13 may include the subject matter of Example 12, and may further specify that the stiffener is shaped as an outer ring around the die.

Example 14 may include the subject matter of Example 12, and may further specify that the die is selected from the group consisting of a central processing unit, a platform controller hub, a memory die, a field programmable gate array silicon die, and graphic processing unit.

Example 15 may include the subject matter of Example 12, and may further specify that the microelectronic assembly is included in a server device.

Example 16 may include the subject matter of Example 12, and may further specify that the microelectronic assembly is included in a portable computing device.

Example 17 may include the subject matter of Example 12, and may further specify that the microelectronic assembly is included in a wearable computing device.

Example 18 is a microelectronic stiffener apparatus, including: a stiffener having a surface, wherein the stiffener includes a cavity and a conductive pathway between the cavity and the surface of the stiffener; and an electrical component, wherein the electrical component is embedded in the cavity and is electrically coupled to the conductive pathway.

Example 19 may include the subject matter of Example 18, and may further include: a package substrate, wherein the surface of the stiffener is attached to a surface of the package substrate, and wherein the electrical component is electrically coupled to the surface of the package substrate via the conductive pathway.

Example 20 may include the subject matter of Example 18, and may further specify that the stiffener includes ceramic.

Example 21 may include the subject matter of Example 18, and may further specify that the stiffener includes a first portion having the conductive pathway and a second portion having the cavity.

Example 22 may include the subject matter of Example 21, and may further specify that the first portion includes first fingers and the second portion includes second fingers that are interdigitated with the first fingers, and wherein the first portion is attached to the second portion by interconnecting the first fingers and the second fingers.

Example 23 may include the subject matter of Example 21, and may further specify that the first portion includes a first conductive contact and the second portion includes a second conductive contact, and wherein the first portion is attached to the second portion by electrically connecting the first conductive contact and the second conductive contact.

Example 24 may include the subject matter of Example 23, and may further specify that the first conductive contact is electrically connected to the second conductive contact by solder.

Example 25 is a computing device, including: a circuit board; and an integrated circuit (IC) package, wherein the IC package includes: a package substrate; and a stiffener having an embedded electrical component and a conductive pathway between the embedded electrical component and a surface of the stiffener, wherein the embedded electrical component is electrically coupled to the package substrate via the conductive pathway.

Example 26 may include the subject matter of Example 25, and may further specify that the embedded electrical component is one of a resistor, a capacitor, an inductor, and a chip-type passive component.

Example 27 may include the subject matter of Example 25, and may further specify that the embedded electrical component is a magnetic inductor array for voltage regulation.

Example 28 may include the subject matter of Example 25, and may further specify that the conductive pathway includes copper.

Example 29 may include the subject matter of Example 25, and may further include: a die coupled to the surface of the package substrate.

Example 30 may include the subject matter of Example 29, and may further specify that the die is one of a central processing unit, a platform controller hub, a memory die, a field programmable gate array silicon die, and graphic processing unit.

Example 31 is a method for fabricating a microelectronic assembly, the method including: forming a cavity on a second surface of a stiffener having a first surface and an opposing second surface; forming a conductive pathway in the stiffener; placing an electrical component having a conductive contact in the cavity; and forming an electrical connection between the conductive contact on the electrical component and the conductive pathway in the stiffener, wherein the conductive pathway extends between a bottom surface of the cavity and the first surface of the stiffener.

Example 32 may include the subject matter of Example 31, and may further include: placing the stiffener on a surface of a package substrate, wherein the first surface of the stiffener faces the surface of the package substrate; and forming an electrical connection between the electrical component and the package substrate via the conductive pathway in the stiffener.

Example 33 may include the subject matter of Example 31, and may further include: placing a lid on a top surface of the cavity.

Example 34 may include the subject matter of Example 31, and may further specify that the electrical component is a magnetic inductor array for voltage regulation.

Example 35. A method for fabricating a microelectronic assembly, the method including: forming a conductive pathway through a first portion of a stiffener; forming a cavity in a second portion of the stiffener; placing an electrical component having a conductive contact on the first portion of the stiffener with the conductive contact facing the first portion of the stiffener; forming an electrical connection between the electrical component and the first portion of the stiffener; and attaching the first portion of the stiffener to the second portion of the stiffener, wherein the cavity opening in the second portion of the stiffener faces the first portion and the electrical component is within the cavity.

Example 36 may include the subject matter of Example 35, and may further specify that the first portion of the stiffener includes first fingers, wherein the second portion of the stiffener includes second fingers that are interdigitated with the first fingers, and where the first portion is attached to the second portion by interconnecting the first fingers and the second fingers.

Example 37 may include the subject matter of Example 35, and may further specify that the first portion includes a first conductive contact, wherein the second portion includes a second conductive contact, and wherein the first portion is attached to the second portion by electrically connecting the first conductive contact and the second conductive contact.

Example 38 may include the subject matter of Example 35, and may further specify that the electrical connection between the conductive contact on the electrical component and the conductive pathway in the stiffener is solder.

Example 39 may include the subject matter of Example 35, and may further include: placing the stiffener on a surface of a package substrate, wherein the first portion of the stiffener faces the surface of the package substrate; and forming an electrical connection between the electrical component and the package substrate via the conductive pathway in the stiffener.

Example 40 is a microelectronic assembly, including: a package substrate; and a stiffener including an embedded electrical component having a conductive contact, wherein the embedded electrical component is electrically coupled to the package substrate via the conductive contact.

Example 41 may include the subject matter of Example 40, and may further specify that the embedded electrical component is an air core inductor for voltage regulation.

Example 42 may include the subject matter of Example 41, and may further specify that an electrical connection between the air core inductor and the package substrate is coupled to a voltage output rail.

Example 43 may include the subject matter of Example 40, and may further specify that the stiffener includes a first portion having the embedded electrical component and a second portion having a conductive pathway between the first portion of the stiffener and the package substrate, and wherein the embedded electrical component is electrically coupled to the package substrate via the conductive pathway.

Example 44 may include the subject matter of Example 43, and may further specify that the first portion includes first fingers and the second portion includes second fingers that are interdigitated with the first fingers, and wherein the first portion is attached to the second portion by interconnecting the first fingers and the second fingers.

Example 45 may include the subject matter of Example 43, and may further specify that the first portion includes a first conductive contact and the second portion includes a second conductive contact, and wherein the first portion is attached to the second portion by electrically connecting the first conductive contact and the second conductive contact.

1. A microelectronic assembly, comprising:
a package substrate;
a stiffener having a surface, wherein the stiffener includes a cavity and a conductive pathway between the cavity and the surface of the stiffener, and wherein the stiffener is coupled to the package substrate such that the surface of the stiffener is between the cavity and the package substrate; and
an electrical component, wherein the electrical component is embedded in the cavity and is electrically coupled to the package substrate via the conductive pathway.

2. The microelectronic assembly of claim 1, wherein the electrical component is a magnetic inductor array.

3. The microelectronic assembly of claim 2, wherein an electrical connection between the magnetic inductor array and the package substrate is coupled to a voltage output rail.

4. The microelectronic assembly of claim 1, wherein the stiffener includes ceramic.

5. The microelectronic assembly of claim 1, wherein the stiffener includes a first portion having first fingers and a second portion having second fingers that are interdigitated with the first fingers, and wherein the first portion is attached to the second portion by interconnecting the first fingers and the second fingers.

6. The microelectronic assembly of claim 1, wherein the stiffener includes a first portion having a first conductive contact and a second portion having a second conductive contact, and wherein the first portion is attached to the second portion by electrically connecting the first conductive contact and the second conductive contact.

7. The microelectronic assembly of claim 1, wherein the electrical component is a first electrical component, the conductive pathway in the stiffener is a first conductive pathway, and the microelectronic assembly further includes:
a second conductive pathway in the stiffener, where the second conductive pathway is between the cavity and the surface of the stiffener; and
a second electrical component, wherein the second electrical component is embedded in the cavity and is electrically coupled to the package substrate via the second conductive pathway.

8. The microelectronic assembly of claim 1, wherein the electrical component is a first electrical component and wherein the cavity is a first cavity, further comprising:
a second cavity in the stiffener having a second conductive pathway, where the second conductive pathway is between the second cavity and the surface of the stiffener; and
a second electrical component, wherein the second electrical component is embedded in the second cavity and is electrically coupled to the package substrate via the second conductive pathway.

9. The microelectronic assembly of claim 1, further comprising:
a die coupled to the surface of the package substrate.

10. The microelectronic assembly of claim 9, wherein the stiffener is shaped as an outer ring around the die.

11. The microelectronic assembly of claim 9, wherein the die is selected from the group consisting of a central processing unit, a platform controller hub, a memory die, a field programmable gate array silicon die, and graphic processing unit.

12. A microelectronic stiffener apparatus, comprising:
a stiffener having a surface, wherein the stiffener includes a cavity and a conductive pathway between the cavity and the surface of the stiffener; and
an electrical component, wherein the electrical component is embedded in the cavity and is electrically coupled to the conductive pathway.

13. The microelectronic stiffener apparatus of claim 12, further comprising:
a package substrate, wherein the surface of the stiffener is attached to a surface of the package substrate, and wherein the electrical component is electrically coupled to the surface of the package substrate via the conductive pathway.

14. The microelectronic stiffener apparatus of claim 12, wherein the stiffener includes a first portion having the conductive pathway and a second portion having the cavity.

15. The microelectronic stiffener apparatus of claim 14, wherein the first portion includes first fingers and the second portion includes second fingers that are interdigitated with the first fingers, and wherein the first portion is attached to the second portion by interconnecting the first fingers and the second fingers.

16. The microelectronic stiffener apparatus of claim 14, wherein the first portion includes a first conductive contact and the second portion includes a second conductive contact, and wherein the first portion is attached to the second portion by electrically connecting the first conductive contact and the second conductive contact.

17. A computing device, comprising:
a circuit board; and
an integrated circuit (IC) package, wherein the IC package comprises:
a package substrate; and
a stiffener having an embedded electrical component and a conductive pathway between the embedded electrical component and a surface of the stiffener, wherein the embedded electrical component is electrically coupled to the package substrate via the conductive pathway.

18. The computing device of claim 17, wherein the embedded electrical component is one of a resistor, a capacitor, an inductor, and a chip-type passive component.

19. The computing device of claim 17, wherein the embedded electrical component is a magnetic inductor array.

20. The computing device of claim 17, wherein the conductive pathway includes copper.

21. The computing device of claim 17, further comprising:
a die coupled to the surface of the package substrate.

22. A method for fabricating a microelectronic assembly, the method comprising:
forming a conductive pathway through a first portion of a stiffener;
forming a cavity in a second portion of the stiffener;
placing an electrical component having a conductive contact on the first portion of the stiffener with the conductive contact facing the first portion of the stiffener;
forming an electrical connection between the electrical component and the first portion of the stiffener; and
attaching the first portion of the stiffener to the second portion of the stiffener, wherein the cavity opening in the second portion of the stiffener faces the first portion and the electrical component is within the cavity.

23. The method of claim 22, wherein the first portion of the stiffener includes first fingers, wherein the second portion of the stiffener includes second fingers that are interdigitated with the first fingers, and where the first portion is attached to the second portion by interconnecting the first fingers and the second fingers.

24. The method of claim 22, wherein the first portion includes a first conductive contact, wherein the second portion includes a second conductive contact, and wherein the first portion is attached to the second portion by electrically connecting the first conductive contact and the second conductive contact.

25. The method of claim 22, further comprising:
placing the stiffener on a surface of a package substrate, wherein the first portion of the stiffener faces the surface of the package substrate; and
forming an electrical connection between the electrical component and the package substrate via the conductive pathway in the stiffener.
